(19) United States
(12) Patent Application Publication
(10) Pub. No.: US 2005/0250056 A1
(43) Pub. Date: Nov. 10, 2005

(54) Substrate treatment method, substrate treatment apparatus, and method of manufacturing semiconductor device

(76) Inventors: Kenji Kawano, Yokohama-shi (JP); Shinichi Ito, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/114,043

(22) Filed: Apr. 26, 2005

(30) Foreign Application Priority Data
Apr. 27, 2004 (JP) 2004-131647

(51) Int. Cl. G03F 7/38

(52) U.S. Cl. 430/330

(57) ABSTRACT

According to an aspect of the present invention, there is provided a substrate treatment method comprising forming a chemically amplified resist film on a substrate to be treated, and supplying heat to the chemically amplified resist film to perform a heat treatment, wherein the heat treatment includes creating a first temperature state satisfying T_{T}<T_{B}, and creating a second temperature state satisfying T_{T}>T_{B} in which T_{T} is a temperature at a surface portion of the chemically amplified resist film, and T_{B} is a temperature at an interface portion of the chemically amplified resist film with the substrate to be treated.

### CROSS-REFERENCE TO RELATED APPLICATIONS

This application is based upon and claims the benefit of priority from prior Japanese Patent Application No. 2004-131647, filed Apr. 27, 2004, the entire contents of which are incorporated herein by reference.

### BACKGROUND OF THE INVENTION

1. Field of the Invention

The present invention relates to a substrate treatment method, a substrate treatment apparatus, and a method of manufacturing a semiconductor device capable of improving the sensitivity of a chemically amplified resist.

2. Description of the Related Art

In manufacturing of semiconductor devices, a resist pattern is formed on a substrate to be processed, before formation of an element area, processing of electrode wiring and the like (lithographic process). Along with shrinkage of a pattern to be processed, a chemically amplified resist is now widely used in the lithography process. The resist pattern using the chemically amplified resist is generally formed as follows. First, a resist film is formed on a semiconductor wafer which is a substrate to be treated, and a predetermined pattern is then transferred by exposure to form a latent image. Then, an acid in the resist film produced during the exposure is diffused by a heat treatment process after the exposure, called post exposure bake (PEB). Subsequently, a development treatment is performed using an alkali developing solution or the like, thereby forming the resist pattern.

It is necessary to reduce the wavelength of a light source during the exposure, in order to form a micro pattern. At present, excimer laser such as KrF or ArF is used and is in practical use as a light source of exposure apparatus, but the pattern formation by DUV light has a limit in pattern resolution, so that low acceleration EB lithography and electron beam projection exposure (EPL) techniques have been developed as next-generation lithography techniques. These lithography processes using the electron beam require more drawing time than photolithography, so that how to improve a throughput is an important technical issue.

On the contrary, it has been conceived to increase the sensitivity of a chemically amplified resist material to be used. However, it has been considered very difficult in the present situation that the optimization of the resist material alone achieves both resist characteristics such as a resist profile and line edge roughness, and the sensitivity required from the throughput.

Furthermore, a method has been reported (M. Cheng et al., J. Vac SciTech. 18 (6), pp. 3318, Nov/Dev 2000) in which a voltage is applied vertically to a resist film during the PEB, in order to substantially improve the sensitivity of the resist. In this report, a pattern having a desired dimension can be formed at a low dose owing to an electric field assist effect during the PEB, and the substantial resist sensitivity improvement is succeeded. However, in this PEB method, because electrodes are directly placed on a resist film surface to apply the voltage during the PEB, the electrodes become contaminated, and the electrodes need to be cleaned every time a treatment is performed. Moreover, intensity of electric field greatly depends on distances between the electrodes and the wafer, so that, for example, it is difficult to apply the voltage uniformly in the wafer surface, and therefore, there are actually many problems to overcome before practical applications.

### BRIEF SUMMARY OF THE INVENTION

According to an aspect of the present invention, there is provided a substrate treatment method comprising: forming a chemically amplified resist film on a substrate to be treated; and supplying heat to the chemically amplified resist film to perform a heat treatment, wherein the heat treatment includes creating a first temperature state satisfying T_{T}<T_{B}, and creating a second temperature state satisfying T_{T}>T_{B} in which T_{T} is a temperature at a surface portion of the chemically amplified resist film, and T_{B} is a temperature at an interface portion of the chemically amplified resist film with the substrate to be treated.

According to another aspect of the present invention, there is provided a method of manufacturing a semiconductor device, comprising: forming a chemically amplified resist film on a substrate to be treated; and supplying heat to the chemically amplified resist film to perform a heat treatment, wherein the heat treatment includes creating a first temperature state satisfying T_{T}<T_{B}, and creating a second temperature state satisfying T_{T}>T_{B} in which T_{T} is a temperature at a surface portion of the chemically amplified resist film, and T_{B} is a temperature at an interface portion of the chemically amplified resist film with the substrate to be treated.

According to another aspect of the present invention, there is provided a substrate treatment apparatus, wherein there are placed in a chamber a first heater disposed on a lower surface side of a substrate to be treated in which a chemically amplified resist film is formed; and a second heater disposed on an upper surface side of the substrate to be treated, the substrate treatment apparatus comprising a controller which controls the first heater and the second heater so that a first temperature state satisfying T_{T}<T_{B} and a second temperature state satisfying T_{T}>T_{B} are created in which T_{T} is a temperature at a surface portion of the chemically amplified resist film, and T_{B} is a temperature at an interface portion of the chemically amplified resist film with the substrate to be treated.

### BRIEF DESCRIPTION OF THE SEVERAL VIEWS OF THE DRAWING

FIG. 1 is a flowchart showing a part of a process of manufacturing a semiconductor device according to one embodiment of the present invention;

FIG. 2 is a sectional view schematically showing a heat treatment apparatus;

FIG. 3 is a diagram showing temperature characteristics at a resist surface (resist top) and an interface portion (resist bottom) with a base antireflection film, with respect to heat treatment time;

FIG. 4A, FIG. 4B, FIG. 4C, FIG. 4D are diagrams schematically showing the movement of an acid in a resist film during heating; and

FIG. 5 is a diagram schematically showing the heat treatment apparatus.

### DETAILED DESCRIPTION OF THE INVENTION

An embodiment of the present invention will be described below referring to the drawings.

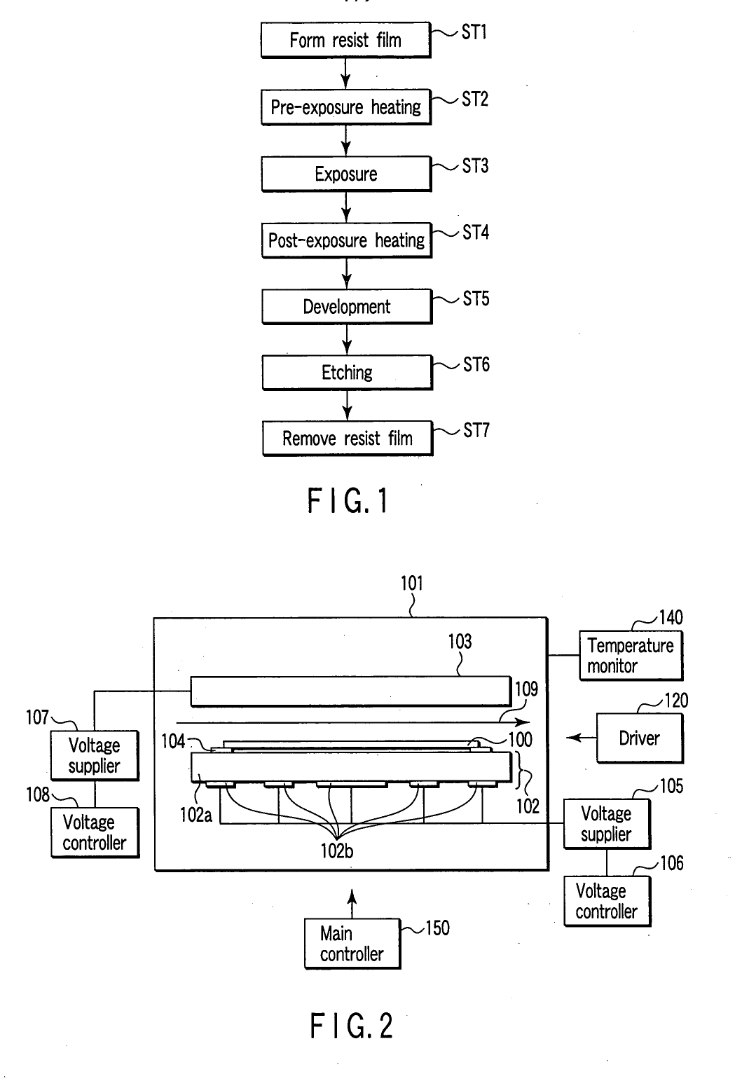

FIG. 1 is a flowchart showing a part of a process of manufacturing a semiconductor device according to one embodiment of the present invention.

A semiconductor substrate having a diameter of 300 mm in the process of manufacturing the semiconductor device is prepared. An antireflection agent is applied onto the semiconductor substrate (substrate to be treated. Hereinafter referred to as a wafer.) by a spin-coating method. Baking treatment is performed at 190° C. for 60 seconds to form an antireflection film having a thickness of 60 nm on the wafer. A positive chemically amplified resist agent is furthermore applied onto the antireflection film (step ST1).

A pre-exposure heat treatment called a pre-bake is performed at 130° C. for 60 seconds to volatilize a solvent in the resist, and a resist film of 300 nm is formed on the antireflection film (step ST2). After the pre-baking, the wafer is cooled down to room temperature, and the wafer is carried to an electron beam writing apparatus. Then, in the electron beam writing apparatus, a periodic pattern of 70 nm line-and-space patterns is drawn at an accelerating voltage of 50 kV (exposure), thereby forming a predetermined latent image (step ST3).

After exposure, the wafer is carried out from the electron beam writing apparatus, and carried to a heat treatment apparatus, and then subjected to a postexposure heat treatment called post exposure bake (PEB) at 130° C. for 90 seconds (step ST4).

Details of the PEB treatment will be described below. FIG. 2 is a sectional view schematically showing the heat treatment apparatus used in the present embodiment. In a chamber 101 of the heat treatment apparatus, there are arranged two heating units: a hot plate 102 to heat a wafer 100 from a rear side; and a light heating unit 103 to heat the wafer 100 from an upper side. The wafer 100 is carried into the chamber 101 by a carrying arm (not shown) or the like, and mounted on the hot plate 102 via a proximity gap 104 having a height of 0.1 mm.

The hot plate 102 comprises a heat homogenizing plate 102a which homogenizes heat distribution and a concentrically divided heater 102b. The temperature of the heater 102b is controlled to a desired value by a voltage controller 106 using voltage supplier 105 and an temperature monitor system 140. The light heating unit 103 is placed above the wafer 100, and light emitted from the light heating unit 103 is applied to a surface of the wafer 100. In the present embodiment, a halogen lamp is used as a light source in the light heating unit 103, and the light is applied to the surface of the wafer 100 via a filter (not shown) which cuts off wavelengths in an ultraviolet region.

The light heating unit 103 comprises a plurality of light emitters, and each light emitter is independently controlled by a voltage controller 108 using a voltage supplier 107, thereby allowing uniform heating in the surface of the wafer 100. Further, the voltage controller 108 allows the temperature on the surface of the resist film to be controlled to a desired value using the voltage supplier 107 and the temperature monitor system 140. Moreover, a purge air flow 109 is formed over the surface of the wafer 100 by an unshown feed port, an exhaust port and a purge air flow forming mechanism. The purge air flow 109 is controllable in terms of an exhaust speed and gas temperature.

In addition, a main controller 150 is connected to the voltage controller 106, the voltage controller 108, the temperature monitor system 140, and a driver 120.

Next, a heating sequence will be described referring to the drawings. Following sequence is performed under control of the main controller 150.

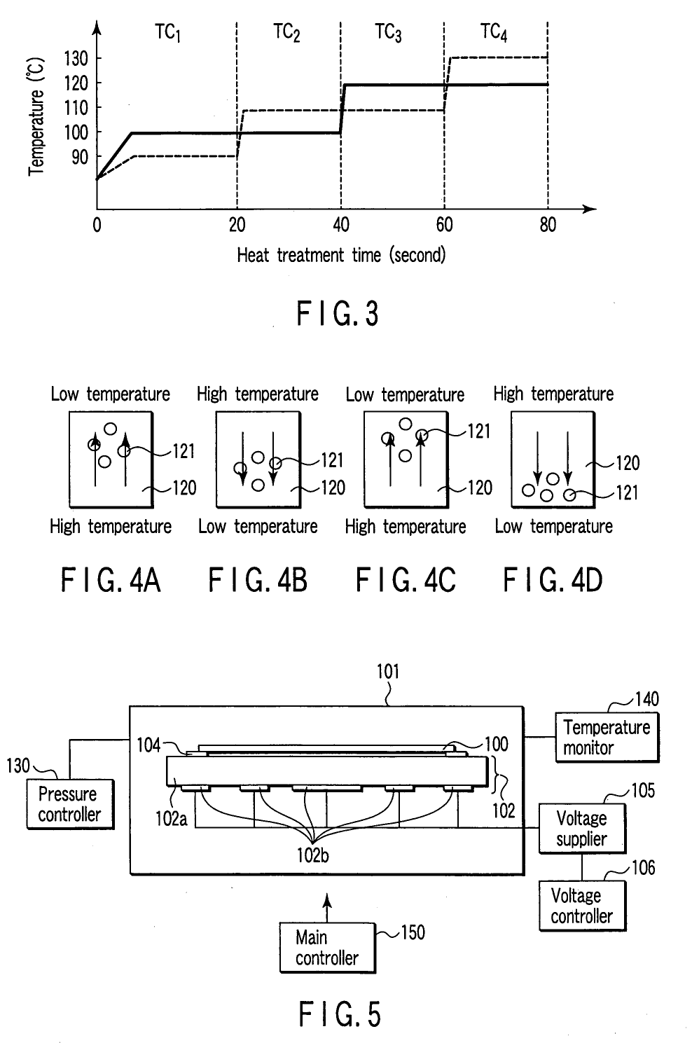

FIG. 3 schematically shows temperature characteristics of the resist film surface (resist top) and an interface portion (resist bottom) between the resist film and a base antireflection film, with respect to heat treatment time, according to the present embodiment. In the drawing, a broken line indicates the temperature at the resist top, and a full line indicates the temperature at the resist bottom. Here, heat treatment starting time is t=0.

At an early stage of heating (fist temperature state TC₁), control is performed so that heat is supplied from the hot plate 102 on the lower surface of the wafer 100. At this time, heat is removed from the resist film top by the purge air flow 109 in the chamber 101. Therefore, the temperature at the resist film bottom is higher than that of the resist film top. A temperature gradient created by the resist film top and bottom applies force in a direction toward the top of a resist film 120 to an acid 121 in the resist film 120, and the acid 121 moves upward (FIG. 4A).

At time t₁=20 seconds, the light heating unit 103 placed above the wafer 100 is powered on, such that the wafer 100 is heated from above, and the temperature at the resist film top will thus be higher than that at the bottom (second temperature state TC₂). In the second temperature state TC₂, force in a direction toward the bottom of the resist film 120 is exerted, so that the acid 121 moves in the direction toward the bottom of the resist film 120 (FIG. 4B).

At time t₂=40 seconds, heater output (amount of heat supplied) of the hot plate 102 placed under the wafer 100 is increased such that the temperature at the bottom of the wafer 100 will be higher than that at the top (third temperature state TC₃). In the third temperature state TC₃, force in the direction toward the top of the resist film 120 is exerted, so that the acid 121 moves in the upward direction of the resist film (FIG. 4C).

At time t₃=60 seconds, the output (amount of heat supplied) of the light heating unit 103 placed above the wafer 100 is further increased, such that the wafer 100 is heated from the top, and the temperature at the top of the resist film 120 will thus be higher than that at the bottom (fourth temperature state TC₄). In the fourth temperature state TC₄, force in the direction toward the bottom of the resist film 120 is exerted, so that the acid 121 moves in the direction toward the bottom (FIG. 4D).

At time t₄=80 seconds, the wafer 100 is carried outside the heat treatment apparatus, carried to a cooling unit (not shown), and cooled down to the room temperature. It is further carried to a developing apparatus, and subjected to a development treatment with an alkali developing solution including TMAH as the main component, thereby forming the resist pattern (step ST5).

The wafer or the film formed on the wafer is etched with the resist pattern as a mask (step ST6). Then, the resist pattern is removed (step ST7).

Finally, the wafer 100 treated as described above is used to manufacture the semiconductor device.

In the conventional PEB method, a dose of 10.2 μC/cm² is required during EB drawing to form a 70 nm line-and-space pattern into a desired dimension, but in the PEB method described in the present embodiment, the desired dimension can be formed at a dose of 5.7 μC/cm², and the sensitivity of the resist film can be substantially improved.

In the present embodiment, the two heating sources are disposed on the upper surface side and lower surface side of the wafer to control temperature, but this is not a limitation. For example, as shown in FIG. 5, one hot plate 102 is disposed on the lower surface side of the wafer 100 in the chamber 101, and the pressure in the chamber 101 is controlled by a pressure controller 130 to control the temperature on the upper surface of the resist film, thus providing the same effects. For example, when a state at pressure P₁, at temperature T₁ in the chamber 101 is brought to a state at pressure P₂, at temperature T₂, it results in temperature T₂=(P₂/P₁)×T₁. A change in temperature in the chamber changes the temperature on the upper surface of the resist film. It is to be noted that the temperature control of the hot plate 102 may be used in combination. Further, control of the amount of supplied heat may be performed not by controlling the amount of generated heat of the hot plate 102 and the light heating unit 103, but by controlling the distance between the wafer 100, and the hot plate 102 and the light heating unit 103. In this case, the wafer 100 is moved upward and downward by the driver 120 between the hot plate 102 and the light heating unit 103 under control of the main controller 150.

The halogen lamp is used as the light source in the present embodiment, but it is not limited thereto and other light sources may be used. The temperature at the bottom of the resist film has been high in the initial condition, but the temperature on the top side of the resist film may be high.

According to the embodiment of the present invention, by changing the relation so that one of the temperature in the surface portion of the chemically amplified resist film and the temperature at the interface portion of the chemically amplified resist film with the substrate to be treated is higher than the other, the sensitivity of the resist film can be improved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A substrate treatment method comprising:
forming a chemically amplified resist film on a substrate to be treated; and
supplying heat to the chemically amplified resist film to perform a heat treatment,
wherein the heat treatment includes
creating a first temperature state satisfying T_{T}<T_{B}, and creating a second temperature state satisfying T_{T}>T_{B}
in which T_{T} is a temperature at a surface portion of the chemically amplified resist film, and T_{B} is a temperature at an interface portion of the chemically amplified resist film with the substrate to be treated.

2. The substrate treatment method according to claim 1, wherein
the first temperature state and the second temperature state
are created by controlling an amount of heat supplied from heat sources disposed above and under the substrate to be treated.

3. The substrate treatment method according to claim 2, wherein the control of the amount of supplied heat is performed by controlling at least one of calorific values of the heat sources and distances between the substrate to be treated and the heat sources.

4. The substrate treatment method according to claim 1, wherein the first temperature state and the second temperature state are created by controlling a pressure during the heat treatment.

5. The substrate treatment method according to claim 4, wherein the first temperature state and the second temperature state are further created by controlling the amount of heat supplied from the heat source disposed under the substrate to be treated.

6. The substrate treatment method according to claim 1, wherein the first temperature state and the second temperature state appear alternately.

7. The substrate treatment method according to claim 1, wherein a transition from the first temperature state to the second temperature state or a transition from the second temperature state to the first temperature state is made by changing one of the temperatures T_{T} and T_{B}.

8. The substrate treatment method according to claim 1, wherein a desired latent image is formed in the chemically amplified resist film by energy line irradiation.

9. The substrate treatment method according to claim 2, wherein the heat source disposed above the substrate to be treated has a light source.

10. A method of manufacturing a semiconductor device, comprising:
forming a chemically amplified resist film on a substrate to be treated; and
supplying heat to the chemically amplified resist film to perform a heat treatment,
wherein the heat treatment includes
creating a first temperature state satisfying T_{T}<T_{B}, and creating a second temperature state satisfying T_{T}>T_{B}
in which T_{T} is a temperature at a surface portion of the chemically amplified resist film, and T_{B} is a temperature at an interface portion of the chemically amplified resist film with the substrate to be treated.

11. The method of manufacturing a semiconductor device according to claim 10, wherein
the first temperature state and the second temperature state
are created by controlling an amount of heat supplied from heat sources disposed above and under the substrate to be treated.

12. The method of manufacturing a semiconductor device according to claim 11, wherein the control of the amount of supplied heat is performed by controlling at least one of calorific values of the heat sources and distances between the substrate to be treated and the heat sources.

13. A substrate treatment apparatus, wherein there are placed in a chamber
a first heater disposed on a lower surface side of a substrate to be treated in which a chemically amplified resist film is formed; and
a second heater disposed on an upper surface side of the substrate to be treated,
the substrate treatment apparatus comprising a controller which controls the first heater and the second heater so that a first temperature state satisfying T_{T}<T_{B} and a second temperature state satisfying T_{T}>T_{B} are created in which T_{T} is a temperature at a surface portion of the chemically amplified resist film, and T_{B} is a temperature at an interface portion of the chemically amplified resist film with the substrate to be treated.

14. The substrate treatment apparatus according to claim 13, wherein the controller creates the first temperature state and the second temperature state by controlling an amount of heat supplied from the first heater and the second heater.

15. The substrate treatment apparatus according to claim 14, wherein the controller controls the amount of supplied heat by controlling at least one of calorific values of the first heater and the second heater and distances between the substrate to be treated and the first heater and the second heater.

16. The substrate treatment apparatus according to claim 13, wherein the controller creates the first temperature state and the second temperature state by controlling a pressure in the chamber.

17. The substrate treatment apparatus according to claim 16, wherein the controller further creates the first temperature state and the second temperature state by controlling the amount of heat supplied from the first heater.

18. The substrate treatment apparatus according to claim 13, wherein the controller controls so that the first temperature state and the second temperature state appear alternately.

19. The substrate treatment apparatus according to claim 13, wherein the controller makes a transition from the first temperature state to the second temperature state or a transition from the second temperature state to the first temperature state by changing one of the temperatures T_{T} and T_{B}.

20. The substrate treatment apparatus according to claim 14, wherein the second heater has a light source.
